(19) United States
(12) Patent Application Publication
(10) Pub. No.: US 2024/0128164 A1
(43) Pub. Date: Apr. 18, 2024

(54) INTEGRATED CIRCUIT INCLUDING THROUGH-SILICON VIA AND METHOD OF DESIGNING THE INTEGRATED CIRCUIT

(71) Applicant: Samsung Electronics Co., Ltd., Suwon-si (KR)

(72) Inventors: Youngrok Park, Suwon-si (KR); Hoyoung Tang, Suwon-si (KR); Taehyung Kim, Suwon-si (KR); Sangshin Han, Suwon-si (KR)

(21) Appl. No.: 18/475,290

(22) Filed: Sep. 27, 2023

(30) Foreign Application Priority Data
Oct. 14, 2022 (KR) 10-2022-0132715

(51) Int. Cl. H01L 23/48; G06F 30/392; G06F 30/394; H01L 23/528

(52) U.S. Cl. CPC H01L 23/481; G06F 30/392; G06F 30/394; H01L 23/5283; H01L 23/5286

(57) ABSTRACT

An integrated circuit may include a bit cell array including a plurality of bit cells and a peripheral region including a peripheral circuit. The peripheral region may include a plurality of devices over a substrate, at least one pattern configured to provide a first voltage to at least one of the plurality of devices, at least one power line extending under the substrate, and at least one first via passing through the substrate in a vertical direction in the peripheral region and electrically connecting the at least one pattern to the at least one power line.

### CROSS-REFERENCE TO RELATED APPLICATION

This application is based on and claims priority under 35 U.S.C. § 119 to Korean Patent Application No. 10-2022-0132715, filed on Oct. 14, 2022, in the Korean Intellectual Property Office, the disclosure of which is incorporated by reference herein in its entirety.

### FIELD

The inventive concept relates to an integrated circuit, and more particularly, to an integrated circuit including a through silicon via and a method of manufacturing the integrated circuit.

### BACKGROUND

Integrated circuits may include devices and patterns for supplying power to the devices. The patterns for supplying the power to the devices may be regularly arranged for stably supplying the power to the devices. As semiconductor processes advance, the size of devices may decrease and routing for signals may be affected by patterns for supplying power.

### SUMMARY

The inventive concept provides an integrated circuit including a through silicon via for supplying power to devices and a method of manufacturing the integrated circuit.

According to an aspect of the inventive concept, there is provided an integrated circuit including a plurality of gate lines extending in a first horizontal direction over a substrate, first to fourth active patterns extending in a second horizontal direction intersecting the first horizontal direction over the substrate, a first pattern extending in the second horizontal direction over a region between the first active pattern and the second active pattern, the first pattern being configured to receive a first voltage, a second pattern extending in the second horizontal direction over a region between the third active pattern and the fourth active pattern, the second pattern being configured to receive a second voltage, at least one first via contacting the first pattern and electrically connecting the first pattern to bodies of devices comprising at least a portion of the first active pattern or the second active pattern, and at least one second via passing through the substrate in a vertical direction and electrically connecting the second pattern to a first power line extending under the substrate.

According to another aspect of the inventive concept, there is provided an integrated circuit including a plurality of gate lines extending in a first horizontal direction over a substrate, first to fourth active patterns extending in a second horizontal direction intersecting the first horizontal direction over the substrate, a first pattern extending in the second horizontal direction over a region between the first active pattern and the second active pattern, the first pattern being configured to receive a first voltage, a second pattern extending in the second horizontal direction over a region between the third active pattern and the fourth active pattern, the second pattern being configured to receive a second voltage, a first via passing through the substrate in a vertical direction and electrically connecting the first pattern to a first power line extending under the substrate, and a second via passing through the substrate in the vertical direction and electrically connecting the second pattern to a second power line extending under the substrate.

According to another aspect of the inventive concept, there is provided an integrated circuit including a bit cell array including a plurality of bit cells and a peripheral region including a peripheral circuit, wherein the peripheral region includes a plurality of devices over a substrate, at least one pattern configured to provide a first voltage to at least one of the plurality of devices, at least one power line extending under the substrate, and at least one first via passing through the substrate in a vertical direction in the peripheral region and electrically connecting the at least one pattern to the at least one power line.

### BRIEF DESCRIPTION OF THE DRAWINGS

Embodiments will be more clearly understood from the following detailed description taken in conjunction with the accompanying drawings in which:

FIGS. 1A and 1B are diagrams illustrating examples of an integrated circuit according to embodiments;

FIG. 2 is a diagram illustrating a layout of an integrated circuit according to an embodiment;

FIGS. 3A, 3B, 3C, and 3D are diagrams illustrating examples of devices according to embodiments;

FIGS. 4A and 4B are plan views illustrating layouts of an integrated circuit according to embodiments;

FIGS. 5A, 5B and 5C are plan views illustrating layouts of an integrated circuit according to embodiments;

FIG. 6 is a plan view illustrating a layout of an integrated circuit according to embodiment;

FIGS. 7A and 7B are plan views illustrating layouts of an integrated circuit according to embodiments;

FIGS. 8A, 8B, and 8C are plan views illustrating layouts of an integrated circuit according to embodiments;

FIG. 9 is a flowchart illustrating a method of manufacturing an integrated circuit, according to an embodiment;

FIG. 10 is a flowchart illustrating a method of designing an integrated circuit, according to an embodiment;

FIG. 11 is a block diagram illustrating a system on chip according to an embodiment; and

FIG. 12 is a block diagram illustrating a computing system including a memory configured for storing a program, according to an embodiment.

### DETAILED DESCRIPTION OF THE EMBODIMENTS

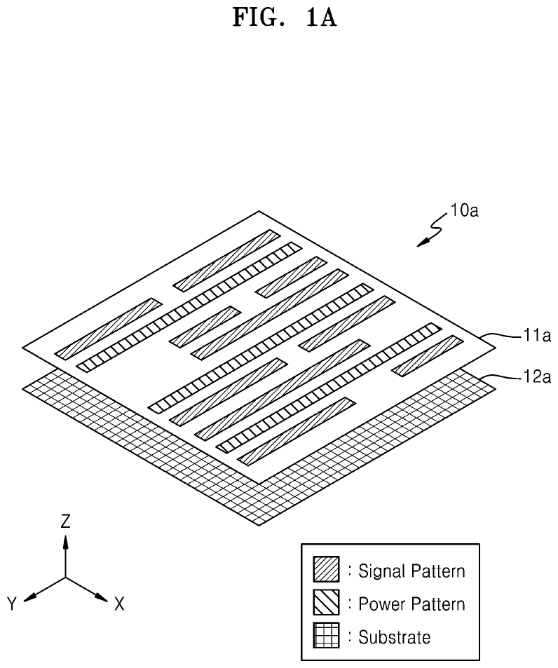

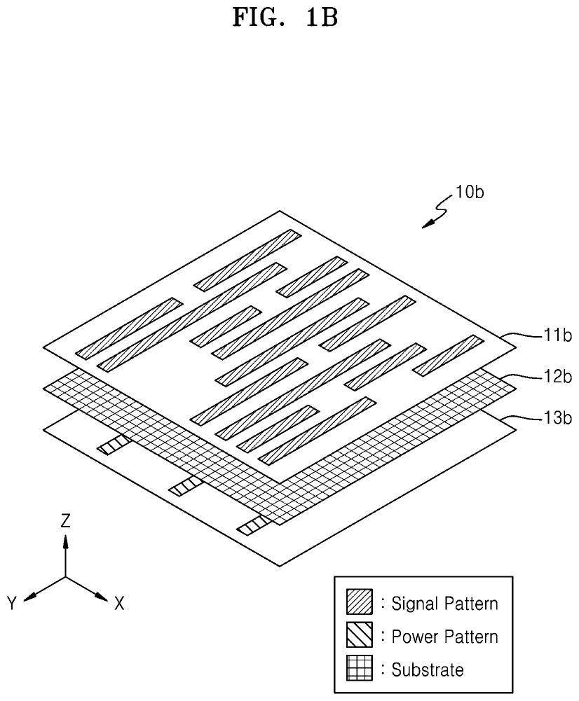

FIGS. 1A and 1B are diagrams illustrating examples of an integrated circuit according to embodiments. Hereinafter, repeated descriptions of FIGS. 1A and 1B may be omitted.

Herein, an X-axis direction may be referred to as a first horizontal direction, a Y-axis direction may be referred to as a second horizontal direction, and a Z-axis direction may be referred to as a vertical direction. The terms “first,” “second,” etc. may be used herein merely to distinguish one element, component, region, or direction from another. A plane based on an X axis and a Y axis may be referred to as a horizontal surface, an element relatively arranged in a +Z direction compared to another element may be referred to as being over the other element, and an element relatively arranged in a −Z direction compared to another element may be referred to as being under the other element. Also, an area of an element may denote a size occupied by the element in a surface parallel to a horizontal surface, and a width of an element may denote a dimension thereof in a direction perpendicular to a direction in which the element extends. A surface exposed in or normal to the +Z direction may be referred to as a top surface, a surface exposed in or normal to the −Z direction may be referred to as a bottom surface, and a surface exposed in or normal to a ±X direction or a ±Y direction may be referred to as a side surface. For convenience of illustration, only some layers may be illustrated in the drawings, and a via connecting an upper pattern with a lower pattern may be illustrated for understanding despite being disposed under the upper pattern. Also, a pattern including a conductive material like a pattern of a wiring layer may be referred to as a conductive pattern, or may be simply referred to as a pattern. The terms “comprises,” “comprising,” “includes” and/or “including,” when used herein, specify the presence of stated elements, but do not preclude the presence of additional elements. The term “and/or” includes any and all combinations of one or more of the associated listed items.

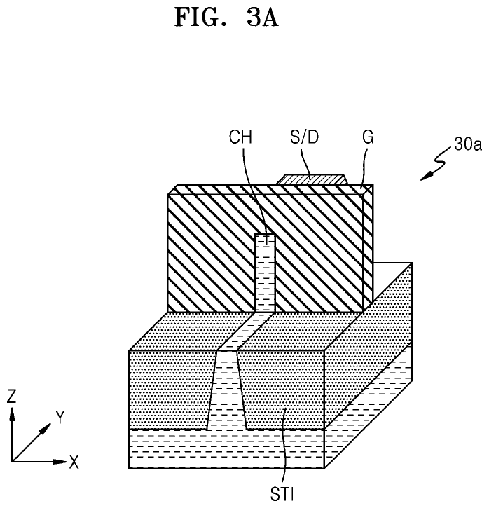

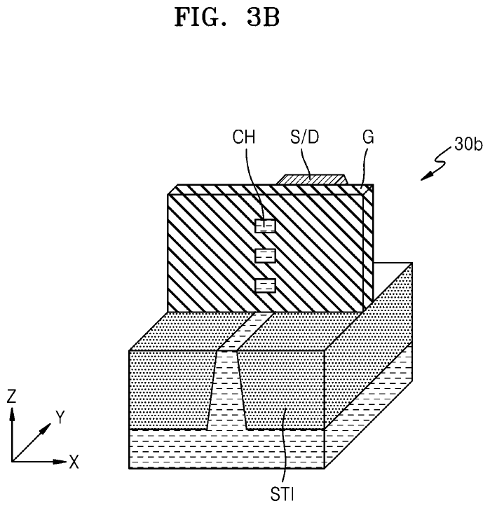

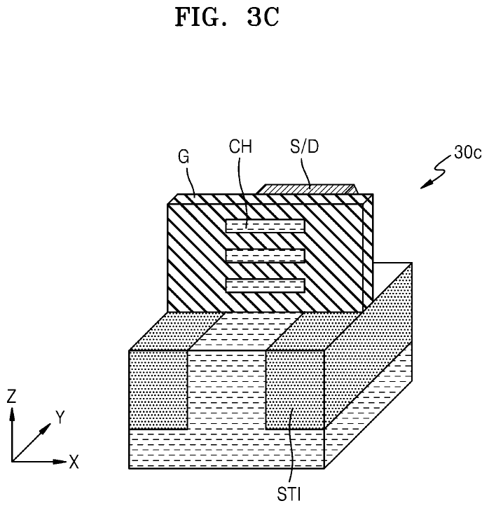

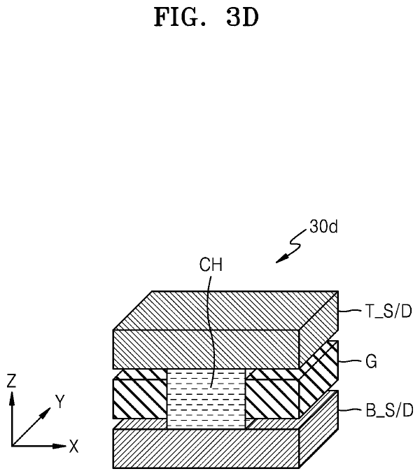

Referring to FIG. 1A, an integrated circuit 10a may include a wiring layer 11a and a substrate 12a. Devices (for example, transistors) may be formed over the substrate 12a, and examples of the devices are described below with reference to FIGS. 3A to 3D. The wiring layer 11a may be disposed over the devices, and patterns including a conductive material may be formed in the wiring layer 11a. For example, as illustrated in FIG. 1A, patterns (herein, may be referred to as signal patterns) for input signals and/or output signals of the devices may be formed in the wiring layer 11a, and patterns (herein, may be referred to as power patterns) for supplying power to the devices may be formed in the wiring layer 11a. In some embodiments, the patterns formed in the wiring layer 11a may include metal, and the wiring layer 11a may be referred to as a metal layer. The integrated circuit 10a may include a plurality of wiring layers, and patterns formed in each of adjacent wiring layers may be electrically connected with (also referred to as electrically connected to) each other through a via. For example, the integrated circuit 10a may include at least one wiring layer between the wiring layer 11a and the substrate 12a and may include at least one wiring layer on the wiring layer 11a.

A supply voltage (for example, a positive supply voltage and/or a negative supply voltage) may be applied to power patterns. For example, the devices may receive the supply voltage, applied to a pad over a plurality of wiring layers, through patterns formed in each of the plurality of wiring layers. As described above, a structure where the supply voltage is provided from above the substrate 12a may be referred to as a front-side power delivery network (FSPDN). In some embodiments, power patterns may be regularly arranged in the wiring layer 11a so that power is stably supplied to the devices, and signal patterns may be disposed in a region, where the power patterns are not provided, of the wiring layer 11a. For example, as illustrated in FIG. 1A, the power patterns may extend in parallel in the Y-axis direction at certain intervals in the wiring layer 11a, and the signal patterns may extend in the Y-axis direction between the power patterns in the wiring layer 11a. As a semiconductor process advances, a size of devices formed on the substrate 12a may decrease, and thus, it may not be easy to form signal patterns for routing input signals and output signals of the devices and the power patterns may increase routing congestion.

Referring to FIG. 1B, an integrated circuit 10b may include a wiring layer 11b, a substrate 12b, and a backside wiring layer 13b. Devices (for example, transistors) may be formed over the substrate 12b. The wiring layer 11b may be disposed over the devices, and the backside wiring layer 13b may be disposed under the substrate 12b. The wiring layer 11b may be referred to as a front-side wiring layer, so as to be differentiated from the backside wiring layer 13b. As illustrated in FIG. 1B, signal patterns may be formed in the wiring layer 11b, and power patterns may be formed in the backside wiring layer 13b. The power patterns may be omitted in the wiring layer 11b, and the signal patterns may be disposed in a region where the power patterns are omitted. Therefore, the integrated circuit 10b of FIG. 1B may provide routability which is greater than that of the integrated circuit 10a of FIG. 1A.

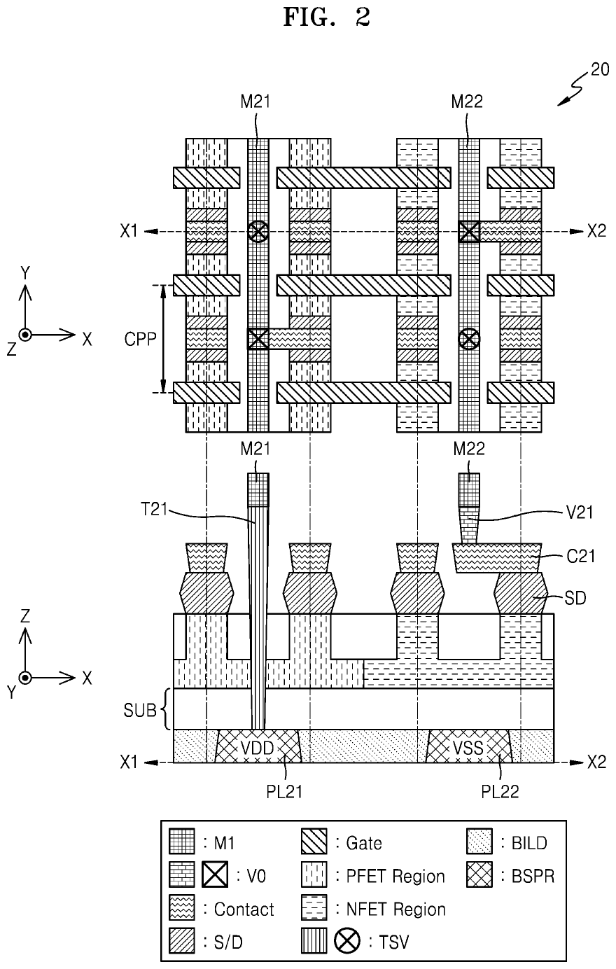

To supply power to a device by using the power patterns formed in the backside wiring layer 13b, the integrated circuit 10b may include a through silicon via (TSV). As described below with reference to FIG. 2, a TSV may be connected with the backside wiring layer 13b and may be connected with a pattern formed in a wiring layer between the wiring layer 11b and the substrate 12b. Elements or components described herein as “connected” to or with one another may be physically and/or electrically connected. Elements or components that are “directly” on or connected to or with one another may be free of intervening elements or components therebetween. Accordingly, the supply voltage may be supplied to devices through the TSV from the power pattern formed in the backside wiring layer 13b. As described above, a structure where the supply voltage is provided from a portion under the substrate 12a may be referred to as a backside power delivery network (BSPDN). Herein, the power pattern formed in the backside wiring layer 13b may be referred to as a power line.

In some embodiments, the TSV may be connected with a pattern formed in a first wiring layer (for example, an M1 layer) closest to the substrate 12b. Patterns formed in the first wiring layer may have a resistance which is higher than that of patterns formed in the other wiring layers, and thus, a device disposed at a relatively long distance from the TSV may receive a decreased positive supply voltage and/or an increased negative supply voltage. As described below with reference to the drawings, the integrated circuit 10b may include TSVs which are disposed so that power is stably supplied to the devices, and thus, the performance and reliability of the integrated circuit 10b may be improved. Also, an additional area for placing TSVs may be omitted, and an increase in area of the integrated circuit 10b may be limited. Also, due to the power patterns disposed in the backside wiring layer 13b, routing resources may increase in front-side wiring layers including the wiring layer 11b, and thus, routing congestion may be alleviated or removed in the integrated circuit 10b.

FIG. 2 is a diagram illustrating a layout of an integrated circuit 20 according to an embodiment. The upper drawing of FIG. 2 is a plan view illustrating a layout of the integrated circuit 20 as seen in a −Z-axis direction, and the lower drawing of FIG. 2 is a cross-sectional view illustrating a cross-sectional surface, taken along line X1-X2, of the layout of the integrated circuit 20.

Referring to FIG. 2, the integrated circuit 20 may include gate lines (or gate electrodes or gates) extending in an X-axis direction and may include p-channel field effect transistor (PFET) regions and n-channel field effect transistor (NFET) regions extending in a Y-axis direction. As illustrated in FIG. 2, a pitch of the gate lines may be referred to as a contact poly pitch (CPP). As described below with reference to FIGS. 3A to 3C, in each of the PFET regions and the NFET regions, portions protruding in a +Z-axis direction and extending in the Y-axis direction may configure an active region of a transistor, and herein, may be referred to as an active pattern. A source/drain may be formed at each of both sides of the gate line, a contact may be formed on the source/drain, and a channel may be formed between source/drains under the gate line. A via of a first via layer VO may be disposed on the contact and may be connected with the contact and a pattern of a first wiring layer M1. For example, as illustrated in FIG. 2, a via V21 may be connected with a contact C21 and a second pattern M22.

The integrated circuit 20 may include a first power line PL21 and a second power line PL22, which extend in the Y-axis direction under a substrate SUB. For example, as illustrated in FIG. 2, the first power line PL21 may extend in the Y-axis direction under the PFET region, and a positive supply voltage VDD may be applied to the first power line PL21. Also, the second power line PL22 may extend in the Y-axis direction under the NFET region, and a negative supply voltage VSS may be applied to the second power line PL22. A backside interlayer dielectric (BILD) may be formed between the first power line PL21 and the second power line PL22.

The integrated circuit 20 may include a TSV which passes through the substrate SUB and is connected with a power line. For example, as illustrated in FIG. 2, a TSV T21 may pass through the PFET region and the substrate SUB and may be connected with the first power line PL21 and a first pattern M21 of the first wiring layer M1. Accordingly, the positive supply voltage VDD may be applied to the first pattern M21, and the devices may receive the positive supply voltage VDD from the first pattern M21. Similarly, the integrated circuit 20 may include a TSV which is connected with the second power line PL22 and the second pattern M22. Accordingly, the negative supply voltage VSS may be applied to the second pattern M22, and the devices may receive the negative supply voltage VSS from the second pattern M22. For example, as illustrated in FIG. 2, a source/drain SD may receive a negative supply voltage from the second pattern M22 through the via V21 and the contact C21. In one embodiment, the power lines (e.g., the first power line PL21 and the second power line PL22) used to provide power from the backside of the substrate as illustrated in FIG. 2 may be referred to as backside power rails (BSPR).

FIGS. 3A to 3D are diagrams illustrating examples of a device according to embodiments. For example, FIG. 3A illustrates a fin field effect transistor (FinFET) 30a, FIG. 3B illustrates a gate-all-around field effect transistor (GAAFET) 30b, FIG. 3C illustrates a multi-bridge channel field effect transistor (MBCFET) 30c, and FIG. 3D illustrates a vertical field effect transistor (VFET) 30d. For convenience of illustration, FIGS. 3A to 3C illustrate a shape where one of two source/drain regions are removed, and FIG. 3D illustrates a cross-sectional surface taken along a line of the VFET 30d and illustrates a surface which is parallel to a plane including an X axis and a Z axis and passes through a channel CH of the VFET 30d.

Referring to FIG. 3A, the FinFET 30a may be configured by a fin-shaped active pattern extending in the Y-axis direction between shallow trench isolations (STIs) and a gate G extending in the X-axis direction. A source/drain S/D may be formed at each of both sides of the gate G, and thus, a source and a drain may be apart from each other in the Y-axis direction. An insulation layer may be formed between the channel CH and the gate G. In some embodiments, the FinFET 30a may be configured by the gate G and a plurality of active patterns which are apart from each other in the Y-axis direction.

Referring to FIG. 3B, the GAAFET 30b may be configured by active patterns (i.e., nanowires), which are apart from one another in a Z-axis direction and extend in the Y-axis direction, and a gate G which extends in the X-axis direction. A source/drain S/D may be formed at each of both sides of the gate G, and thus, a source and a drain may be apart from each other in the Y-axis direction. An insulation layer may be formed between the channel CH and the gate G. The number of nanowires included in the GAAFET 30b is not limited to the illustration of FIG. 3B.

Referring to FIG. 3C, the MBCFET 30c may be configured by active patterns (i.e., nanosheets), which are apart from one another in a Z-axis direction and extend in the Y-axis direction, and a gate G which extends in the X-axis direction. A source/drain S/D may be formed at each of both sides of the gate G, and thus, a source and a drain may be apart from each other in the Y-axis direction. An insulation layer may be formed between the channel CH and the gate G. The number of nanosheets included in the MBCFET 30c is not limited to the illustration of FIG. 3C.

Referring to FIG. 3D, the VFET 30d may include a top source/drain T_S/D and a bottom source/drain B_S/D, which are apart from each other in a Z-axis direction with a channel CH therebetween. The VFET 30d may include a gate G which surrounds a perimeter of the channel CH, between the top source/drain T_S/D and the bottom source/drain B_S/D. An insulation layer may be formed between the channel CH and the gate G.

Hereinafter, an integrated circuit including the FinFET 30a or the MBCFET 30c is mainly described, but devices included in the integrated circuit are not limited to the embodiments of FIGS. 3A to 3D. For example, the integrated circuit may include a ForkFET having a structure where nanosheets for a P-type transistor are separated from nanosheets for an N-type transistor by a dielectric wall, and thus, the N-type transistor is closer to the P-type transistor. Also, the integrated circuit may include a bipolar junction transistor as well as an FET such as a complementary FET (CFET), a negative capacitance FET (NCFET), or a carbon nanotube FET (CNTFET).

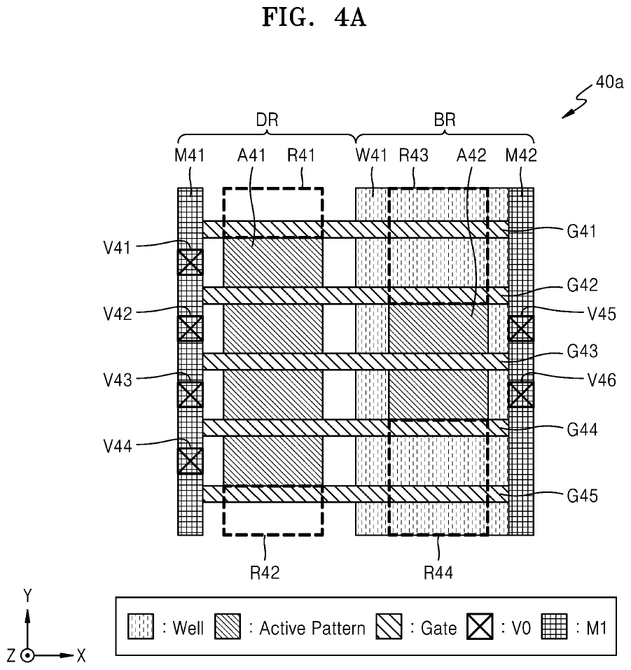

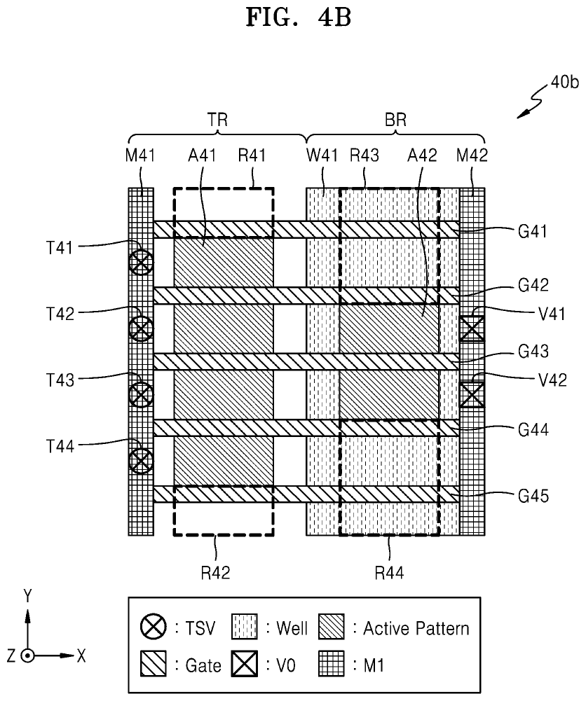

FIGS. 4A and 4B are plan views illustrating layouts of an integrated circuit according to embodiments. For example, the plan view of FIG. 4A illustrates an integrated circuit 40a including a structure for biasing a well W41, and the plan view of FIG. 4B illustrates an integrated circuit 40b including a TSV and a structure for biasing a well W41. Hereinafter, repeated descriptions of FIGS. 4A and 4B may be omitted.

Referring to FIG. 4A, the integrated circuit 40a may include first to fifth gate lines G41 to G45 extending in an X-axis direction, and may include a first active pattern A41 and a second active pattern A42 each extending in a Y-axis direction. In other words, the active patterns A41, A42 may be adjacent one another in the X-axis direction and may extend along the Y-axis direction (also referred to herein as extending side-by-side in the Y-axis direction). The integrated circuit 40a may include a first pattern M41 and a second pattern M42 of a first wiring layer M1 extending in the Y-axis direction over the first to fifth gate lines G41 to G45. The integrated circuit 40a may include a well W41 extending in the Y-axis direction under the second active pattern A42. The well W41 may have a conductive type which differs from a portion (i.e., a substrate) under the first active pattern A41. Accordingly, the first active pattern A41 and the second active pattern A42 may respectively configure complementary transistors. For example, the well W41 and the substrate may be respectively doped N type and P type, and thus, an NFET may be configured by the first active pattern A41 and a PFET may be configured by the second active pattern A42. Hereinafter, it may be assumed that the well W41 is doped N type, and it may be assumed that the substrate is doped P type.

Each of the substrate and the well W41 may be biased. For example, the well W41 may be biased to a positive supply voltage VDD, and the substrate may be biased to a negative supply voltage VSS. The integrated circuit 40a may include a structure for biasing each of the well W41 and the substrate, and a corresponding structure may be referred to as a tap structure. For example, the positive supply voltage VDD may be applied to the second pattern M42, and a fifth via V45 and a sixth via V46 may be connected with the second active pattern A42 through contacts. In the second active pattern A42, a source/drain may be doped N type, and thus, the positive supply voltage VDD may be supplied to the well W41. In some embodiments, the negative supply voltage VSS may be applied to the first pattern M41.

In a portion of the second active pattern A42 configuring a PFET, the source/drain may be doped P type. Therefore, the second active pattern A42 may be cut (e.g., may include a discontinuity or may be removed) at a boundary between a portion doped P type and a portion doped N type. For example, as illustrated in FIG. 4A, the second active pattern A42 may be removed in a third region R43 and a fourth region R44. Due to a semiconductor process of manufacturing the integrated circuit 40a, it may not be easy to dope only the source/drain of the second active pattern A42 of FIG. 4A as an N type. Accordingly, the semiconductor process may dope, as an N type, a source/drain of the first active pattern A41 adjacent to the second active pattern A42 and the source/drain of the second active pattern A42. As a result, the integrated circuit 40a may include a bias region BR for biasing the well W41 and a dummy region DR adjacent to the bias region BR. The first active pattern A41 in the dummy region DR may be cut in the first region R41 and the second region R42. In some embodiments, sources/drains of the first active pattern A41 may be respectively connected with the first to fourth vias V41 to V44 through contacts, and thus, the negative supply voltage VSS may be applied to the sources/drains of the first active pattern A41.

Referring to FIG. 4B, the integrated circuit 40b may include first to fifth gate lines G41 to G45 extending in an X-axis direction and may include a first active pattern A41 and a second active pattern A42 each extending in a Y-axis direction. The integrated circuit 40b may include a first pattern M41 and a second pattern M42 of a first wiring layer M1 extending in the Y-axis direction over the first to fifth gate lines G41 to G45. The integrated circuit 40b may include a well W41 extending in the Y-axis direction under the second active pattern A42. The first active pattern A41 may be removed in a first region R41 and a second region R42, and the second active pattern A42 may be removed in a third region R43 and a fourth region R44.

In some embodiments, the integrated circuit 40b may include a TSV region TR adjacent to a bias region BR and may include at least one TSV in the TSV region TR. For example, as illustrated in FIG. 4B, the integrated circuit 40b may include the bias region BR corresponding to the bias region BR of FIG. 4A and may include the TSV region TR which differs from the dummy region DR of FIG. 4A. First to fourth TSVs T41 to T44 may be disposed in the TSV region TR, and each of the first to fourth TSVs T41 to T44 may be connected with a power line extending under the substrate and the first pattern M41. For example, a negative supply voltage VSS may be applied to the power line, and thus, the first pattern M41 may receive the negative supply voltage VSS through the first to fourth TSVs T41 to T44. As illustrated in FIG. 4B, each of the first to fourth TSVs T41 to T44 may be disposed between two adjacent gate lines and may have a diameter which is less than a CPP. Herein, each of the first to fourth TSVs T41 to T44 may be referred to as a nano TSV.

As described above with reference to FIG. 4A, due to a semiconductor process, a dummy region DR adjacent to the bias region BR may be needed. The integrated circuit 40b of FIG. 4B may use, as the TSV region TR, the dummy region DR adjacent to the bias region BR, and thus, may have the same area as that of the integrated circuit 40a of FIG. 4A and may include a TSV which is connected with the power line.

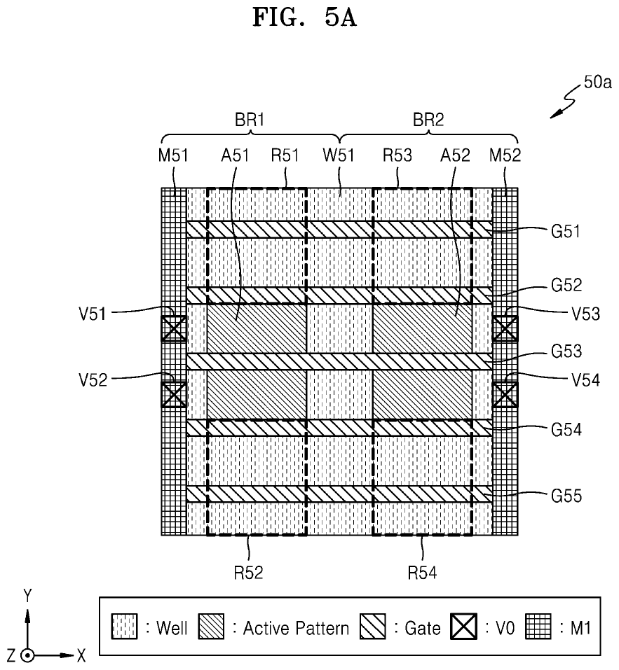

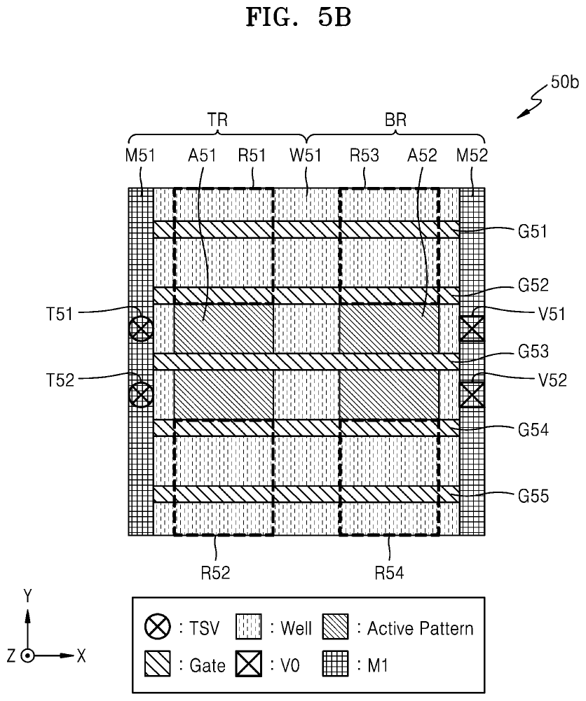

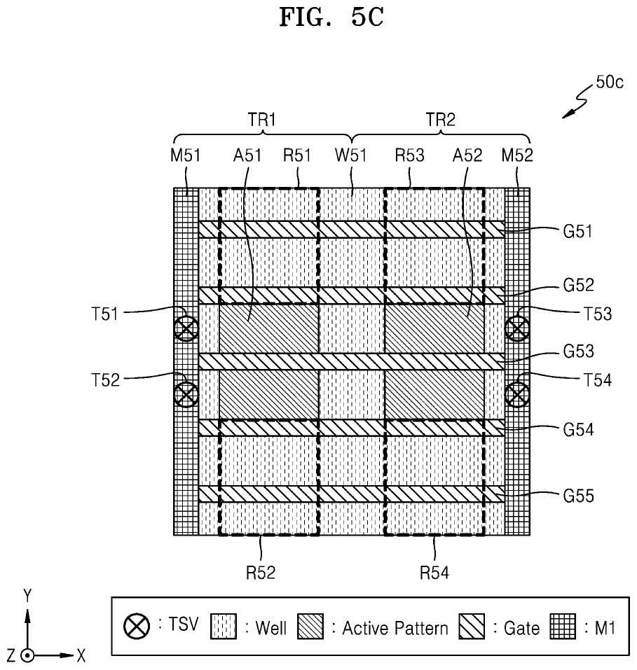

FIGS. 5A to 5C are plan views illustrating layouts of an integrated circuit according to embodiments. For example, the plan view of FIG. 5A illustrates an integrated circuit 50a including a structure (i.e., a tap structure) for biasing a well W51, the plan view of FIG. 5B illustrates an integrated circuit 50b including a TSV and a structure for biasing a well W51, and the plan view of FIG. 5C illustrates an integrated circuit 50c including a TSV. Hereinafter, repeated descriptions of FIGS. 5A to 5C may be omitted.

Referring to FIG. 5A, the integrated circuit 50a may include first to fifth gate lines G51 to G55 extending in an X-axis direction and may include a first active pattern A51 and a second active pattern A52 each extending in a Y-axis direction. The integrated circuit 50a may include a first pattern M51 and a second pattern M52 of a first wiring layer M1 extending in the Y-axis direction on the first to fifth gate lines G51 to G55. The integrated circuit 50a may include a well W51 which extends in the Y-axis direction under the first active pattern A51 and the second active pattern A52. As described above with reference to FIG. 4A, the first active pattern A51 may be removed in a first region R51 and a second region R52, and the second active pattern A52 may be removed in a third region R53 and a fourth region R54.

A positive supply voltage VDD may be applied to the first pattern M51 and the second pattern M52, the first via V51 and the second via V52 may be connected with a source/drain of the first active pattern A51 through contacts, and the third via V53 and the fourth via V54 may be connected with a source/drain of the second active pattern A52 through contacts. In the first active pattern A51 and the second active pattern A52, a source/drain may be doped N type, and thus, a positive supply voltage VDD may be supplied to the well W51. That is, the integrated circuit 50a may include a first bias region BR1 and a second bias region BR2 for biasing the well W51, and the first bias region BR1 may be adjacent to the second bias region BR2.

Referring to FIG. 5B, the integrated circuit 50b may include first to fifth gate lines G51 to G55 extending in an X-axis direction and may include a first active pattern A51 and a second active pattern A52 each extending in a Y-axis direction. The integrated circuit 50b may include a first pattern M51 and a second pattern M52 of a first wiring layer M1 extending in the Y-axis direction over the first to fifth gate lines G51 to G55. The integrated circuit 50b may include a well W51 which extends in the Y-axis direction under the first active pattern A51 and the second active pattern A52. The first active pattern A51 may be removed in a first region R51 and a second region R52, and the second active pattern A52 may be removed in a third region R53 and a fourth region R54.

In some embodiments, the integrated circuit 50b may include a TSV region TR adjacent to a bias region BR and may include at least one TSV in the TSV region TR. For example, as illustrated in FIG. 5B, the integrated circuit 50b may include the bias region BR corresponding to the second bias region BR2 of FIG. 5A and may include the TSV region TR which differs from the first bias region BR1 of FIG. 5A. A first TSV T51 and a second TSV T52 may be disposed in the TSV region TR, and the first TSV T51 and the second TSV T52 may be connected with a power line extending under a substrate and the first pattern M51. For example, a positive supply voltage VDD may be applied to the power line, and thus, the first pattern M51 may receive the positive supply voltage VDD through the first TSV T51 and the second TSV T52. As illustrated in FIG. 5B, each of the first TSV T51 and the second TSV T52 may be a nano TSV.

Referring to FIG. 5C, the integrated circuit 50c may include first to fifth gate lines G51 to G55 extending in an X-axis direction and may include a first active pattern A51 and a second active pattern A52 each extending in a Y-axis direction. The integrated circuit 50c may include a first pattern M51 and a second pattern M52 of a first wiring layer M1 extending in the Y-axis direction on the first to fifth gate lines G51 to G55. The integrated circuit 50c may include a well W51 which extends in the Y-axis direction under the first active pattern A51 and the second active pattern A52. The first active pattern A51 may be removed in a first region R51 and a second region R52, and the second active pattern A52 may be removed in a third region R53 and a fourth region R54.

In some embodiments, the integrated circuit 50c may include TSV regions adjacent to each other. For example, as illustrated in FIG. 5C, the integrated circuit 50c may include a first TSV region TR1 corresponding to the TSV region TR of FIG. 5B and may include a second TSV region TR2 which differs from the second bias region BR2 of FIG. 5A and the bias region BR of FIG. 5B. A first TSV T51 and a second TSV T52 may be disposed in the first TSV region TR1, and the first TSV T51 and the second TSV T52 may be connected with a power line extending under a substrate and the first pattern M51. For example, a positive supply voltage VDD may be applied to the power line, and thus, the first pattern M51 may receive the positive supply voltage VDD through the first TSV T51 and the second TSV T52. Also, a third TSV T53 and a fourth TSV T54 may be disposed in the second TSV region TR2, and the third TSV T53 and the fourth TSV T54 may be connected with the power line extending under the substrate and the second pattern M52. For example, the positive supply voltage VDD may be applied to the power line, and thus, the second pattern M52 may receive the positive supply voltage VDD through the third TSV T53 and the fourth TSV T54. As illustrated in FIG. 5C, each of the first to fourth TSVs T51 to T54 may be a nano TSV.

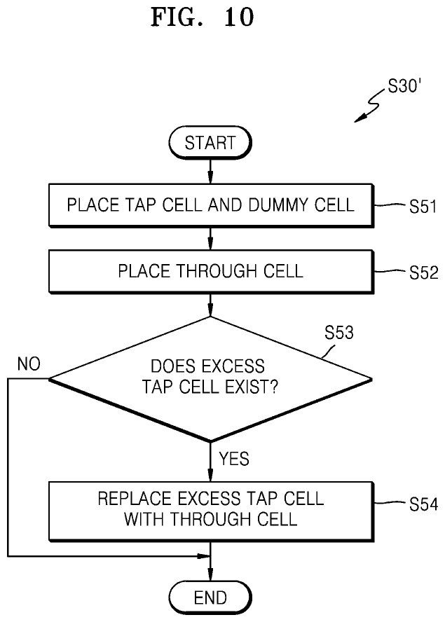

When structures for biasing the well W51 are sufficient, as illustrated in FIGS. 5B and 5C, an integrated circuit may include TSVs in a TSV region. For example, as described below with reference to FIG. 10, when it is determined that bias regions are sufficiently disposed in a layout of an integrated circuit in a design process of the integrated circuit, at least one bias region may be replaced with at least one TSV region and the integrated circuit may include a TSV in the at least one TSV region. Accordingly, a TSV may be provided without an increase in area of an integrated circuit, and thus, devices of the integrated circuit may be stably supplied with power.

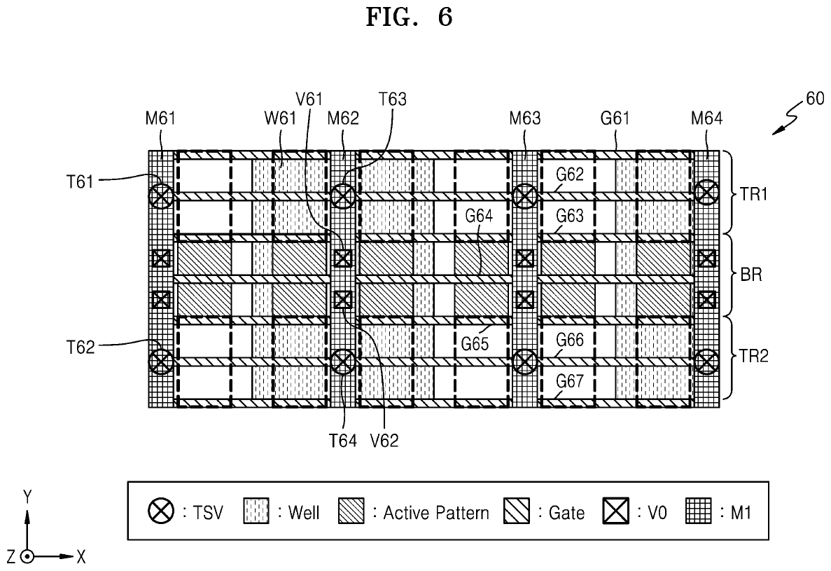

FIG. 6 is a plan view illustrating a layout of an integrated circuit 60 according to embodiment. In describing FIG. 6, descriptions which are the same as or similar to descriptions given above with reference to the drawings may be omitted.

Referring to FIG. 6, the integrated circuit 60 may include first to seventh gate lines G61 to G67 extending in an X-axis direction and may include active patterns extending in a Y-axis direction. The integrated circuit 60 may include first to fourth patterns M61 to M64 of a first wiring layer M1 extending in the Y-axis direction on gate lines. The integrated circuit 60 may include a well extending in the Y-axis direction under a corresponding active pattern.

In some embodiments, the integrated circuit 60 may include a TSV which passes through a gate line. For example, as illustrated in FIG. 6, a first TSV T61 and a third TSV T63 may be disposed between the first gate line G61 and the third gate line G63 and may pass through the second gate line G62 between the first gate line G61 and the third gate line G63. Also, a second TSV T62 and a fourth TSV T64 may pass through the sixth gate line G66 between the fifth gate line G65 and the seventh gate line G67. Each TSV of FIG. 6 may have a diameter which is greater than that of a nano TSV disposed between two gate lines (i.e., disposed in 1CPP) described above with reference to the drawings, and thus, may be disposed within 2CPP.

In some embodiments, the integrated circuit 60 may include a structure for biasing a well between TSVs. For example, a positive supply voltage VDD may be applied to the second pattern M62 of the first wiring layer M1, and a first via V61 and a second via V62 each connected with the second pattern M62 may provide the positive supply voltage VDD to a well W61 through a contact and a source/drain doped N type. Therefore, as illustrated in FIG. 6, a first TSV region TR1 may be formed between the first gate line G61 and the third gate line G63, a bias region BR may be formed between the third gate line G63 and the fifth gate line G65, and a second TSV region TR2 may be formed between the fifth gate line G65 and the seventh gate line G67.

In some embodiments, active patterns adjacent to a TSV may be removed. For example, as illustrated in FIG. 6, active patterns may be removed between the first gate line G61 and the third gate line G63, and active patterns may be removed between the fifth gate line G65 and the seventh gate line G67.

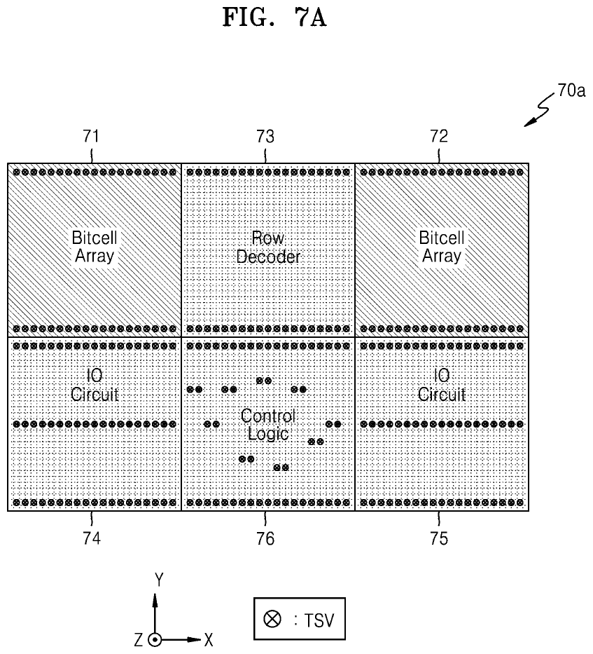

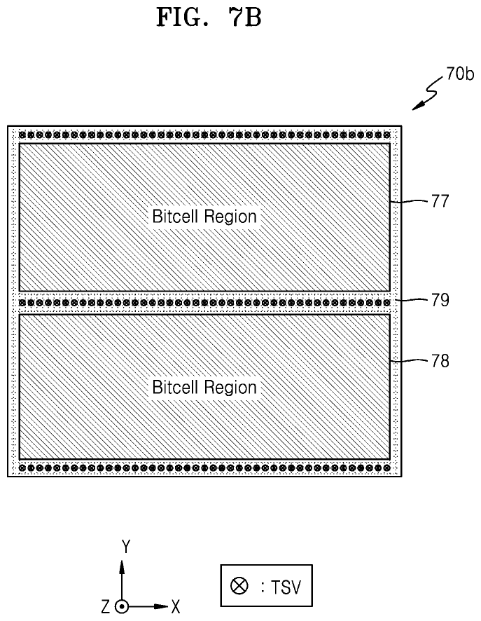

FIGS. 7A and 7B are plan views illustrating layouts of an integrated circuit according to embodiments. For example, the plan views of FIGS. 7A and 7B illustrate layouts of an integrated circuit including a memory cell.

Referring to FIG. 7A, an integrated circuit 70a may include memory cells for storing data and a peripheral circuit for controlling the memory cells. For example, as illustrated in FIG. 7A, the integrated circuit 70a may include a first bit cell array 71 and a second bit cell array 72 each including a plurality of bit cells. The bit cell may store at least one bit or may output the at least one stored bit, based on control by the peripheral circuit. In some embodiments, the bit cell may be a non-volatile memory cell like flash memory or resistive random access memory (RRAM), or may be a volatile memory cell like dynamic random access memory (DRAM) or static random access memory (SRAM). Examples of the first bit cell array 71 and the second bit cell array 72 are described below with reference to FIG. 7B.

The integrated circuit 70a may include a row decoder 73, a first input/output (I/O) circuit 74, a second I/O circuit 75, and a control logic 76, which are peripheral circuits. Herein, a region where a peripheral circuit is disposed may be referred to as a peripheral region. The row decoder 73 may control bit cells corresponding to an address in the first bit cell array 71 and the second bit cell array 72, based on control by the control logic 76. The first I/O circuit 74 and the second I/O circuit 75 may provide the first bit cell array 71 and the second bit cell array 72 with a signal corresponding to write data, or may generate a signal, corresponding to read data, from a signal output from each of the first bit cell array 71 and the second bit cell array 72, based on control by the control logic 76. The control logic 76 may control the row decoder 73, the first I/O circuit 74, and the second I/O circuit 75 in response to a signal (for example, a command) provided from the outside.

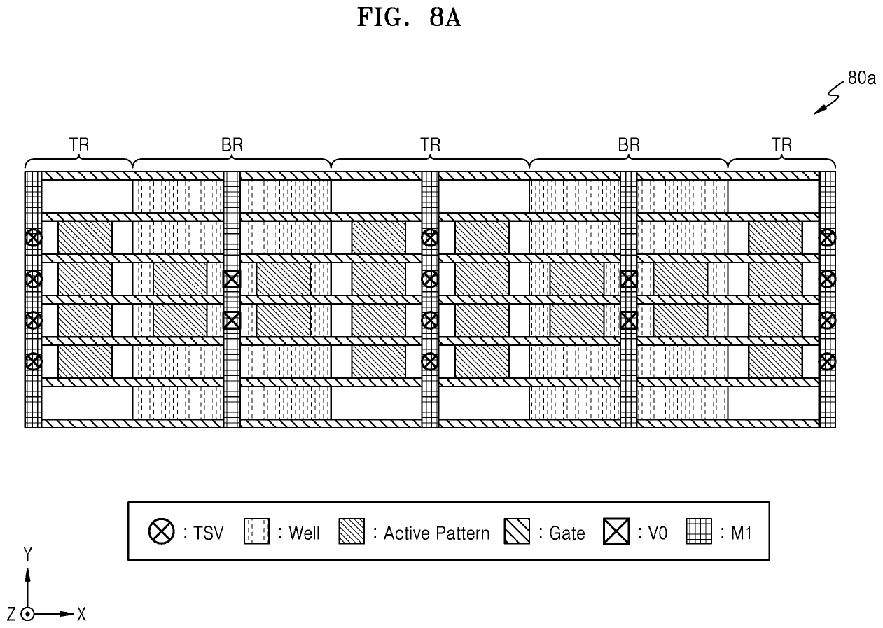

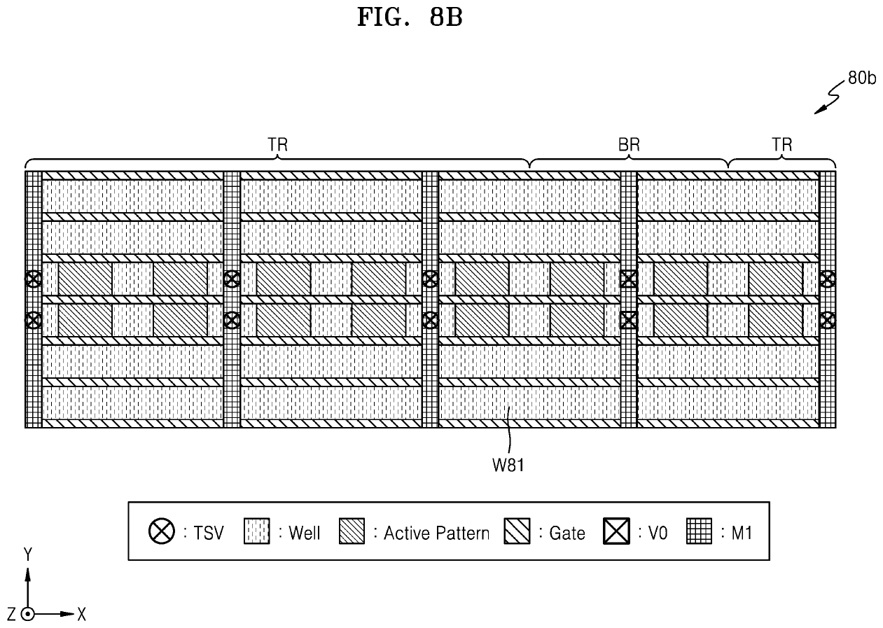

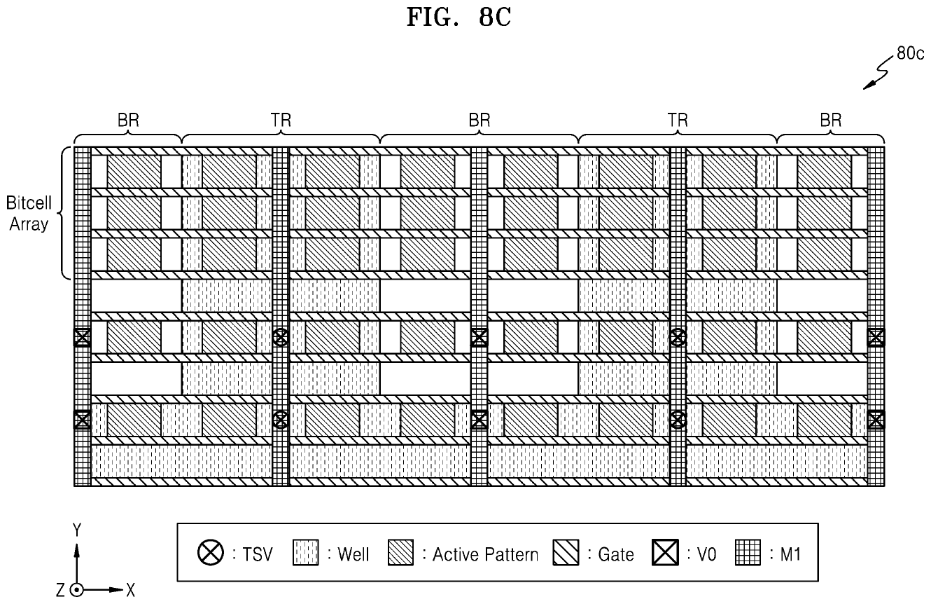

In some embodiments, the integrated circuit 70a may include TSVs disposed in a peripheral circuit and/or a bit cell array. For example, as illustrated in FIG. 7A, the TSVs may be disposed adjacent to edges of the first bit cell array 71, the second bit cell array 72, and the row decoder 73. Also, the TSVs may be disposed in edges of the first I/O circuit 74, the second I/O circuit 75, and the control logic 76, and moreover, may be disposed in inner portions apart from the edges thereof. As described above with reference to the drawings, a TSV may be disposed in a TSV region that replaces or is otherwise provided in a dummy region adjacent to a bias region, or may be disposed in a TSV region that replaces or is otherwise provided in the bias region (e.g., an excess bias region). Accordingly, in FIG. 7A, TSVs disposed in a bit cell array and/or a peripheral circuit may not cause an increase in area of the integrated circuit 70a. Examples of TSVs disposed in a bit cell array and/or a peripheral circuit in the integrated circuit 70a are described below with reference to FIGS. 8A to 8C.

Referring to FIG. 7B, an integrated circuit may include a bit cell array 70b. As described above with reference to FIG. 7A, the bit cell array 70b may include a plurality of bit cells, and a peripheral circuit may be disposed adjacent to the bit cell array 70b. As illustrated in FIG. 7B, the bit cell array 70b may include a first bit cell region 77, a second bit cell region 78, and an auxiliary region 79. In some embodiments, the bit cell array 70b may include three or more bit cell regions.

Each of the first bit cell region 77 and the second bit cell region 78 may include a plurality of bit cells, and the auxiliary region 79 may include dummy cells and/or tap cells. As described above with reference to the drawings, the tap cell may bias a substrate or a well and may have the same dimension (for example, a length thereof in an X-axis direction and/or a length thereof in a Y-axis direction) as that of the bit cell. Also, the dummy cell may be adjacent to the tap cell and may have the same dimension (for example, a length thereof in the X-axis direction and/or a length thereof in the Y-axis direction) as that of the bit cell.

The bit cell array 70b may include TSVs disposed therein. For example, as illustrated in FIG. 7B, the TSVs may be disposed in the auxiliary region 79 and may be disposed between the first bit cell region 77 and the second bit cell region 78. In some embodiments, as described above with reference to the drawings, the TSV may be disposed in the dummy cell.

FIGS. 8A to 8C are plan views illustrating layouts of an integrated circuit according to embodiments. For example, the plan views of FIGS. 8A to 8C illustrate examples of layouts of an integrated circuit including a memory cell. Hereinafter, FIGS. 8A to 8C are described with reference to FIG. 7A.

Referring to FIG. 8A, an integrated circuit 80a may include gate lines extending in an X-axis direction and may include active patterns extending in a Y-axis direction. The integrated circuit 80a may include wells extending in the Y-axis direction under active patterns in a substrate. The integrated circuit 80a may include patterns extending in the Y-axis direction in a first wiring layer M1 on gate lines. In some embodiments, as illustrated in FIG. 8A, the integrated circuit 80a may include a bias region BR and a TSV region TR, which are alternately arranged. The bias region BR may include a via of a first via layer VO connected with a pattern of the first wiring layer M1, and the TSV region TR may include a TSV connected with the pattern of the first wiring layer M1. In some embodiments, a structure of FIG. 8A may be in a peripheral region where the peripheral circuit is provided.

Referring to FIG. 8B, an integrated circuit 80b may include gate lines extending in an X-axis direction and may include active patterns extending in a Y-axis direction. The integrated circuit 80b may include wells extending in the Y-axis direction under active patterns in a substrate. The integrated circuit 80b may include patterns extending in the Y-axis direction in a first wiring layer M1 over gate lines. In some embodiments, the integrated circuit 80b may include a well extending under three or more adjacent active patterns and may include a TSV region TR and a bias region BR each overlapping the well. Components or layers described with reference to “overlap” in a particular direction may be at least partially obstructed by one another when viewed along a line extending in the particular direction or in a plane perpendicular to the particular direction. For example, as illustrated in FIG. 8B, the integrated circuit 80b may include a well W81 having a wide width (i.e., a long length thereof in the X-axis direction) and may include a TSV region TR and a bias region BR each overlapping the well W81. The bias region BR may include a via of a first via layer VO connected with a pattern of the first wiring layer M1, and the TSV region TR may include a TSV connected with the pattern of the first wiring layer M1. In some embodiments, a structure of FIG. 8B may be in an edge of a peripheral region.

Referring to FIG. 8C, an integrated circuit 80c may include gate lines extending in an X-axis direction and may include active patterns extending in a Y-axis direction. The integrated circuit 80c may include wells extending in the Y-axis direction under active patterns in a substrate. The integrated circuit 80c may include patterns extending in the Y-axis direction in a first wiring layer M1 on gate lines. In some embodiments, as illustrated in FIG. 8C, the integrated circuit 80c may include a bias region BR and a TSV region TR, which are alternately arranged. The bias region BR may include a via of a first via layer VO connected with a pattern of the first wiring layer M1, and the TSV region TR may include a TSV connected with the pattern of the first wiring layer M1. In some embodiments, a structure of FIG. 8C may be in an edge of a peripheral region.

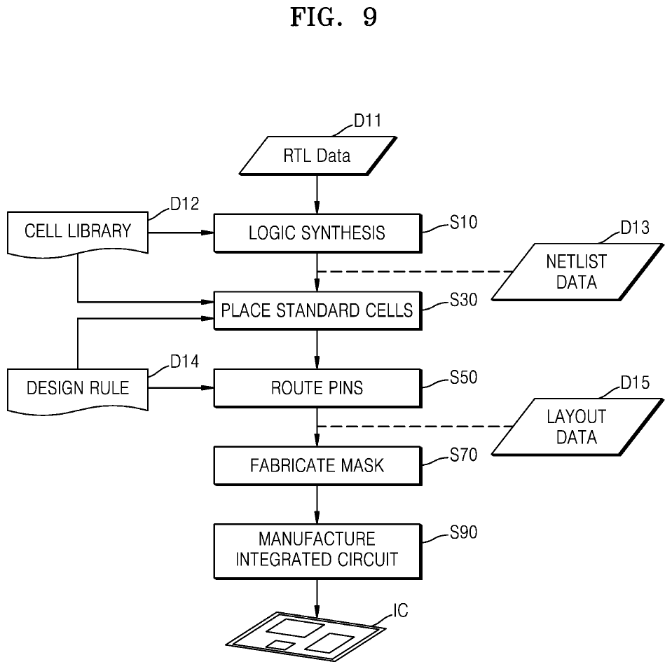

FIG. 9 is a flowchart illustrating a method of manufacturing an integrated circuit IC, according to an embodiment. In detail, the flowchart of FIG. 9 illustrates an example of a method of manufacturing the integrated circuit IC including standard cells. The standard cell may be a unit of a layout included in the integrated circuit IC and may be simply referred to as a cell. The cell may include a transistor and may be designed to perform a predetermined function. For example, the standard cell may have a certain length in the X-axis direction in FIG. 4A, and for example, may have a length corresponding to a pitch of the first pattern M41 and the second pattern M42. As illustrated in FIG. 9, the method of manufacturing the integrated circuit IC may include a plurality of operations S10, S30, S50, S70, and S90.

A cell library (or a standard cell library) D12 may include information about the standard cells (for example, information about a function, a characteristic, a layout, etc.). In some embodiments, the cell library D12 may define a tap cell and a dummy cell as well as function cells which generate an output signal from an input signal. In some embodiments, the cell library D12 may define the tap cell including a bias region and a dummy region. Also, the cell library D12 may define a standard cell including a TSV. As described above with reference to the drawings, in some embodiments, a standard cell including the TSV may have the same size as that of the tap cell and/or the dummy cell. Herein, a standard cell including the TSV may be referred to as a through cell.

A design rule D14 may include requirements which the layout of the integrated circuit IC has to observe. For example, the design rule D14 may include requirements such as a space between widths, a minimum width of a pattern, and a routing direction of a wiring layer, in the same layer. In some embodiments, the design rule D14 may define a minimum separation distance in the same track of the wiring layer.

In operation S10, a logic synthesis operation of generating netlist data D13 from register-transfer-level (RTL) data D11 may be performed. For example, a semiconductor design tool (for example, a logic synthesis tool) may perform logic synthesis with reference to the cell library D12 from the RTL data D11 written in a hardware description language (HDL) such as a very high speed integrated circuit (VHSIC) hardware description language (VHDL) and Verilog and may generate the netlist data D13 including a bitstream or a netlist. The netlist data D13 may correspond to an input of place and routing (P&R) described below.

In operation S30, standard cells may be placed. For example, the semiconductor design tool (for example, a P&R tool) may place standard cells used in the netlist data D13 with reference to the cell library D12. In some embodiments, the semiconductor design tool may place standard cells in a row extending in the Y-axis direction, and the placed standard cell may receive power from a power line extending in the Y-axis direction under a transistor. An example of operation S30 is described below with reference to FIG. 10.

In operation S50, pins of the standard cells may be routed. For example, the semiconductor design tool may generate interconnections which electrically connect input pins and output pins of placed standard cells and may generate layout data D15 which defines the placed standard cells and the generated interconnections. The interconnection may include a via of a via layer and/or a pattern of a wiring layer. The layout data D15 may have, for example, a format, such as GDSII, and may include geometric information about the interconnections and the cells. The semiconductor design tool may refer to the design rule D14 while routing the pins of the cells. The layout data D15 may correspond to an output of place and routing. Operation S50 or operation S30 and operation S50 may be referred to as a method of designing an integrated circuit.

In operation S70, an operation of fabricating a mask may be performed. For example, optical proximity correction (OPC) for correcting distortion, such as refraction caused by a characteristic of light in photolithography, may be applied to the layout data D15. Patterns on a mask may be defined for forming patterns provided in a plurality of layers, based on data to which OPC is applied, and at least one mask (or a photomask) for forming the patterns of each of the plurality of layers may be fabricated. In some embodiments, the layout of the integrated circuit IC may be restrictively modified in operation S70, and an operation of restrictively modifying the integrated circuit IC in operation S70 may be post-processing for optimizing a structure of the integrated circuit IC and may be referred to as design polishing.

In operation S90, an operation of manufacturing the integrated circuit IC may be performed. For example, a plurality of layers may be patterned by using at least one mask which is manufactured in operation S70, and thus, the integrated circuit IC may be manufactured. A front-end-of-line (FEOL) may include, for example, an operation of planarizing and cleaning a wafer, an operation of forming a trench, an operation of forming a well, an operation of forming a gate electrode, and an operation of forming a source and a drain, and based on the FEOL, individual devices (for example, a transistor, a capacitor, and a resistor) may be formed on a substrate. Also, a back-end-of-line (BEOL) may include, for example, an operation of performing silicidation of a gate region, a source region, and a drain region, an operation of adding a dielectric, an operation of forming a hole, an operation of adding a metal layer, an operation of forming a via, and an operation of forming a passivation layer, and based on the BEOL, the individual devices (for example, the transistor, the capacitor, and the resistor) may be connected with one another. In some embodiments, a middle-of-line (MOL) may be performed between the FEOL and the BEOL, and contacts may be formed on the individual devices. Subsequently, the integrated circuit IC may be packaged in a semiconductor package and may be used as parts of various applications.

FIG. 10 is a flowchart illustrating a method of designing an integrated circuit, according to an embodiment. For example, the flowchart of FIG. 10 illustrates an example of operation S30 of FIG. 9. As described above with reference to FIG. 9, standard cells may be placed in operation S30′ of FIG. 10. As illustrated in FIG. 10, operation S30′ may include a plurality of operations S51 to S54.

Referring to FIG. 10, a tap cell and a dummy cell may be placed in operation S51. For example, the semiconductor design tool may place the tap cell so as to bias a substrate and/or a well, and the dummy cell may be placed adjacent to the tap cell. In some embodiments, the design rule D14 of FIG. 9 may define the number of tap cells needed per unit area, and the semiconductor design tool may place the tap cell and the dummy cell with reference to the design rule D14. The semiconductor design tool may place function cells in a region where the tap cell and the dummy cell are placed. In some embodiments, when the dummy cell including a bias region and a dummy region is defined in the cell library D12, the semiconductor design tool may omit placement of the dummy cell.

In operation S52, a through cell may be placed. For example, similar to the description of FIG. 4B, the semiconductor design tool may replace the dummy cell, which is placed in operation S51, with the through cell, and thus, the through cell may be placed. Accordingly, the through cell may be placed in the integrated circuit without an increase in area of the integrated circuit.

In operation S53, whether there is an excess tap cell may be determined. For example, the semiconductor design tool may identify the excess tap cell of the tap cells which are placed in operation S51. In some embodiments, the semiconductor design tool may identify, as the excess tap cell, a tap cell which is greater than the number of tap cells per unit area defined in the design rule D14. As illustrated in FIG. 10, when there is an excess tap cell, operation S54 may be performed subsequently.

In operation S54, the excess tap cell may be replaced with a through cell. For example, similar to the descriptions of FIGS. 5A to 5C, the semiconductor design tool may replace the excess tap cell of the tap cells, which are placed in operation S51, with the through cell. Accordingly, the through cell may be placed in the integrated circuit without disturbing biasing of a substrate and/or a well or increasing an area of the integrated circuit.

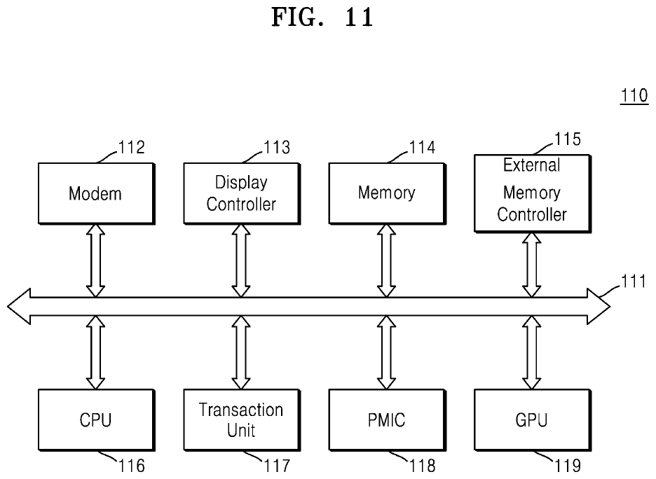

FIG. 11 is a block diagram illustrating a system on chip (SoC) 110 according to an embodiment. The SoC 110 may be a semiconductor device and may include an integrated circuit according to an embodiment. In the SoC 110, like intellectual property (IP) performing various functions, complicated blocks may be implemented in one chip, and based on a method of designing an integrated circuit according to embodiments, the SoC 110 may be designed and thus may have high performance and efficiency. Referring to FIG. 11, the SoC 110 may include a modem 112, a display controller 113, a memory 114, an external memory controller 115, a central processing unit (CPU) 116, a transaction unit 117, a power management integrated circuit (PMIC) 118, and a graphics processing unit (GPU) 119, and the function blocks of the SoC 110 may communicate with one another through a bus 111.

The CPU 116 for controlling an operation of the SoC 110 in an uppermost layer may control operations of the other function blocks (112 to 119). The modem 112 may demodulate a signal received from the outside of the SoC 110, or may modulate a signal generated by the SoC 110 and may transmit a modulated signal to the outside. The external memory controller 115 may control an operation of transmitting or receiving data to or from an external memory device connected with the SoC 110. For example, a program and/or data stored in the external memory device may be provided to the CPU 116 or the GPU 119, based on control by the external memory controller 115. The GPU 119 may execute program instructions associated with graphics processing. The GPU 119 may receive graphics data through the external memory controller 115 and may transmit graphics data, obtained through processing by the GPU 119, to the outside of the SoC 110 through the external memory controller 115. The transaction unit 117 may monitor data transactions of the function blocks, and the PMIC 118 may control power supplied to each of the function blocks, based on control by the transaction unit 117. The display controller 113 may control a display (or a display device) outside the SoC 110 and may thus transmit data, generated by the SoC 110, to the display. The memory 114 may include a non-volatile memory, such as electrically erasable programmable read-only memory (EEPROM) or flash memory, or may include a volatile memory, such as DRAM or SRAM.

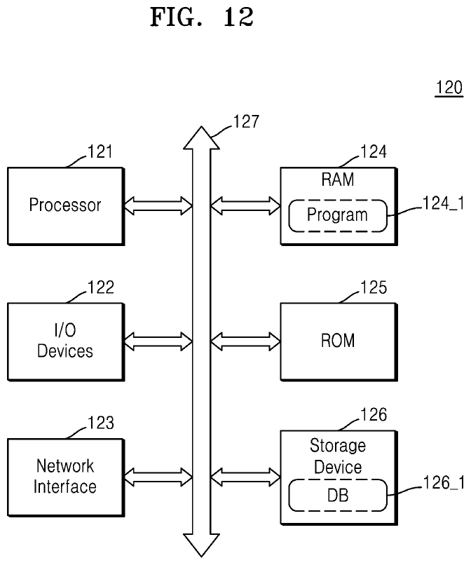

FIG. 12 is a block diagram illustrating a computing system 120 including a memory storing a program, according to an embodiment. A method of designing an integrated circuit according to embodiments (for example, at least some of the operations of the flowchart described above) may be performed by the computing system (or a computer) 120.

The computing system 120 may be a stationary computing system, such as a desktop computer, a workstation, or a server, or may be a portable computing system, such as a laptop computer. As illustrated in FIG. 12, the computing system 120 may include a processor 121, input/output (I/O) devices 122, a network interface 123, random access memory (RAM) 124, read only memory (ROM) 125, and a storage device 126. The processor 121, the I/O devices 122, the network interface 123, the RAM 124, the ROM 125, and the storage device 126 may be connected with the bus 127 and may communicate with one another through the bus 127.

The processor 121 may be referred to as a processing unit, and for example, may include at least one core for executing an arbitrary instruction set (for example, Intel Architecture-32 (IA-32), 64 bit extension IA-32, x86-64, PowerPC, Sparc, MIPS, ARM, or IA-64) such as a microprocessor, an application processor (AP), a digital signal processor (DSP), or a GPU. For example, the processor 121 may access a memory (for example, the RAM 124 or the ROM 125) through the bus 127 and may execute instructions stored in the RAM 124 or the ROM 125.

The RAM 124 may store a program 124_1 for the method of designing the integrated circuit according to an embodiment or at least a portion thereof, and the program 124_1 may allow the processor 121 to perform the method of designing the integrated circuit (for example, at least some of the operations included in the methods of FIG. 9). That is, the program 124_1 may include a plurality of instructions executable by the processor 121, and the plurality of instructions included in the program 124_1 may allow the processor 121 to perform, for example, at least some of the operations included in the flowcharts described above.

The storage device 126 may not erase data stored therein even when power supplied to the computing system 120 is cut off. For example, the storage device 126 may include a non-volatile memory device, or may include a storage medium, such as magnetic tape, an optical disk, or a magnetic disk. Also, the storage device 126 may be detachably attached on the computing system 120. The storage device 126 may store the program 124_1 according to an embodiment, and the program 124_1 or at least a portion thereof may be loaded from the storage device 126 into the RAM 124 before the program 124_1 is executed by the processor 121. On the other hand, the storage device 126 may store a file written in a program language, and the program 124_1 generated from the file by a compiler or at least a portion thereof may be loaded into the RAM 124. Also, as illustrated in FIG. 12, the storage device 126 may store a database (DB) 1261, and the DB 126_1 may include information (for example, information about designed blocks or the cell library D12 and/or the design rule D14 of FIG. 9) needed for designing an integrated circuit.

The storage device 126 may store data, which is to be processed by the processor 121, or data obtained through processing by the processor 121. That is, the processor 121 may process data stored in the storage device 126 to generate data, based on the program 124_1, and may store the generated data in the storage device 126. For example, the storage device 126 may store the RTL data D11, the netlist data D13, and/or the layout data D15 of FIG. 9.

The I/O devices 122 may include an input device such as a keyboard or a pointing device and may include an output device such as a display device or a printer. For example, a user may trigger execution of the program 124_1 by using the processor 121 through the I/O devices 122, input the RTL data D11 and/or the netlist data D13 of FIG. 9, or check the layout data D15 of FIG. 9.

The network interface 123 may provide access to a network outside the computing system 120. For example, the network may include a plurality of computing systems and communication links, and the communication links may include wired links, optical links, wireless links, or arbitrary type of links.

Hereinabove, exemplary embodiments have been described in the drawings and the specification. Embodiments have been described by using the terms described herein, but this has been merely used for describing the inventive concept and has not been used for limiting a meaning or limiting the scope of the inventive concept defined in the following claims. Therefore, it may be understood by those of ordinary skill in the art that various modifications and other equivalent embodiments may be implemented from the inventive concept.

While the inventive concept has been particularly shown and described with reference to embodiments thereof, it will be understood that various changes in form and details may be made therein without departing from the scope of the following claims.

1. An integrated circuit comprising:
a plurality of gate lines extending in a first horizontal direction over a substrate;
first, second, third, and fourth active patterns extending in a second horizontal direction intersecting the first horizontal direction over the substrate;
a first pattern extending in the second horizontal direction over a region between the first active pattern and the second active pattern, wherein the first pattern is configured to receive a first voltage;
a second pattern extending in the second horizontal direction over a region between the third active pattern and the fourth active pattern, wherein the second pattern is configured to receive a second voltage;
at least one first via contacting the first pattern and electrically connecting the first pattern to one or more bodies of devices comprising at least a portion of the first active pattern or the second active pattern; and
at least one second via passing through the substrate in a vertical direction, and electrically connecting the second pattern to a first power line extending under the substrate.

2. The integrated circuit of claim 1, further comprising:
a first well extending in the second horizontal direction over the substrate and overlapping the first active pattern and the second active pattern in the vertical direction,
wherein the first pattern and the at least one first via are electrically connected to the first well.

3. The integrated circuit of claim 2, wherein the first well overlaps the third active pattern and the fourth active pattern in the vertical direction, and the at least one second via passes through the first well.

4. The integrated circuit of claim 1, wherein the first pattern and the at least one first via are electrically connected to the substrate.

5. The integrated circuit of claim 1, further comprising:
a fifth active pattern extending in the second horizontal direction over the substrate, the fifth active pattern being adjacent to the fourth active pattern;
a sixth active pattern extending in the second horizontal direction over the substrate, the sixth active pattern being adjacent to the fifth active pattern;
a third pattern extending in the second horizontal direction over a region between the fifth active pattern and the sixth active pattern, wherein the third pattern is configured to receive the first voltage; and
at least one third via contacting the third pattern and electrically connecting the third pattern to a second power line extending under the substrate.

6. The integrated circuit of claim 5, further comprising:
a first well extending in the second horizontal direction over the substrate and overlapping the first, second, third, fourth, fifth, and sixth active patterns in the vertical direction,
wherein the first pattern and the at least one first via are electrically connected to the first well.

7. The integrated circuit of claim 1, wherein each of the at least one second via passes through the substrate in a vertical direction between two adjacent gate lines of the plurality of gate lines.

8. The integrated circuit of claim 1, wherein portions of the second active pattern adjacent to the at least one second via and portions of the third active pattern adjacent to the at least one first via have a same conductive type.

9. The integrated circuit of claim 1, wherein the plurality of gate lines comprise:
a first gate line group crossing devices included in a bit cell array; and
a second gate line group crossing devices included in a peripheral circuit, and
the at least one first via and the at least one second via are in a peripheral region comprising the peripheral circuit.

10. The integrated circuit of claim 1, wherein the first pattern and the second pattern are in a first wiring layer closet to the plurality of gate lines.

11. An integrated circuit comprising:
a plurality of gate lines extending in a first horizontal direction over a substrate;
first, second, third, and fourth active patterns extending in a second horizontal direction intersecting the first horizontal direction over the substrate;
a first pattern extending in the second horizontal direction over a region between the first active pattern and the second active pattern, wherein the first pattern is configured to receive a first voltage;
a second pattern extending in the second horizontal direction over a region between the third active pattern and the fourth active pattern, wherein the second pattern is configured to receive a second voltage;
a first via passing through the substrate in a vertical direction and electrically connecting the first pattern to a first power line extending under the substrate; and
a second via passing through the substrate in the vertical direction and electrically connecting the second pattern to a second power line extending under the substrate.

12. The integrated circuit of claim 11, wherein the gate lines comprise first, second, and third gate lines, wherein the first via passes through the first gate line in the vertical direction between the second gate line and the third gate line, which are each adjacent to the first gate line, and
the second via passes through the first gate line in the vertical direction between the second gate line and the third gate line.

13. The integrated circuit of claim 12, wherein respective portions of the first, second, third, and fourth active patterns are cut between the second gate line and the third gate line.

14. The integrated circuit of claim 11, further comprising:
at least one third via contacting the first pattern and electrically connecting the first pattern to one or more devices comprising the first active pattern and the second active pattern; and
at least one fourth via contacting the second pattern and electrically connecting the second pattern to one or more bodies of devices comprising at least a portion of the third active pattern or the fourth active pattern.

15. The integrated circuit of claim 14, further comprising:
a first well extending in the second horizontal direction in the substrate and overlapping the first active pattern and the second active pattern in the vertical direction, wherein the first pattern and the at least one third via are electrically connected to the first well.

16. The integrated circuit of claim 14, wherein the first pattern and the at least one third via are electrically connected to the substrate.

17. The integrated circuit of claim 11, wherein the plurality of gate lines comprise:
a first gate line group crossing devices included in a bit cell array; and
a second gate line group crossing devices included in a peripheral circuit, and
the first via and the second via are in a peripheral region comprising the peripheral circuit.

18. (canceled)

19. An integrated circuit comprising:
a bit cell array including a plurality of bit cells; and
a peripheral region including a peripheral circuit, wherein
the peripheral region comprises:
a plurality of devices over a substrate;
at least one pattern configured to provide a first voltage to at least one of the plurality of devices;
at least one power line extending under the substrate; and
at least one first via passing through the substrate in a vertical direction in the peripheral region and electrically connecting the at least one pattern to the at least one power line.

20. The integrated circuit of claim 19, further comprising:
at least one second via passing through the substrate in the vertical direction and electrically connecting the at least one pattern to the at least one power line, the at least one second via being adjacent to a boundary between the bit cell array and the peripheral region.

21. The integrated circuit of claim 19, wherein the peripheral region comprises a plurality of sub-regions respectively corresponding to a plurality of circuits included in the peripheral circuit, and
the at least one first via is adjacent to boundaries between the plurality of sub-regions.

22-23. (canceled)
